(19) United States
(12) Patent Application Publication
(10) Pub. No.: US 2015/0334323 A1
(43) Pub. Date: Nov. 19, 2015

(54) SOLID-STATE IMAGING DEVICE

(71) Applicant: Kabushiki Kaisha Toshiba, Minato-ku (JP)

(72) Inventor: Yoshitaka EGAWA, Yokohama (JP)

(73) Assignee: Kabushiki Kaisha Toshiba, Minato-ku (JP)

(21) Appl. No.: 14/636,517

(22) Filed: Mar. 3, 2015

(30) Foreign Application Priority Data
May 16, 2014 (JP) 2014-102263

(51) Int. Cl. H04N 5/369; H04N 5/374; H04N 5/3745

(52) U.S. Cl. CPC H04N 5/3698; H04N 5/37457; H04N 5/3742

(57) ABSTRACT

According to one embodiment, a solid-state imaging device includes a division transistor that divides a voltage converting unit that converts charges generated by a photo diode into a voltage into a first voltage converting unit at a read transistor side and a second voltage converting unit at an amplifying transistor side.

### CROSS-REFERENCE TO RELATED APPLICATIONS

This application is based upon and claims the benefit of priority from Japanese Patent Application No. 2014-102263, filed on May 16, 2014; the entire contents of which are incorporated herein by reference.

### FIELD

Embodiments described herein relate generally to a solid-state imaging device.

### BACKGROUND

In solid-state imaging devices, when the capacity of a voltage converting unit that converts charges generated by pixels into a voltage is increased in order to increase a saturation electron number, a conversion gain decreases, and an image quality at a time of low luminance shooting is lowered.

### BRIEF DESCRIPTION OF THE DRAWINGS

FIG. 1 is a block diagram illustrating a schematic configuration of a solid-state imaging device according to a first embodiment;

FIG. 2 is a circuit diagram illustrating an exemplary pixel configuration of the solid-state imaging device of FIG. 1;

FIG. 3A is a timing chart illustrating voltage waveforms of respective components when a pixel of FIG. 2 performs a first read operation, and FIG. 3B is a timing chart illustrating voltage waveforms of respective components when the pixel of FIG. 2 performs a second read operation;

FIG. 4A is a cross-sectional view illustrating a schematic configuration a part of the pixel of FIG. 2, and FIGS. 4B to 4E are diagrams illustrating a potential distribution from a time t1 to a time t4 of FIG. 3A in the configuration of FIG. 4A;

FIG. 5A is a cross-sectional view illustrating a schematic configuration of a part of the pixel of FIG. 2, FIG. 5B is a diagram illustrating a potential distribution of the configuration of FIG. 5A in the first read operation, and FIG. 5C is a diagram illustrating a potential distribution of the configuration of FIG. 5A in the second read operation;

FIG. 6A is a cross-sectional view illustrating a schematic configuration of a pixel of a solid-state imaging device according to a second embodiment, FIG. 6B is a diagram illustrating a potential distribution of the configuration of FIG. 6A in the first read operation, and FIG. 6C is a diagram illustrating a potential distribution of the configuration of FIG. 6A in the second read operation;

FIG. 7 is a circuit diagram illustrating an exemplary pixel configuration of a solid-state imaging device according to a third embodiment;

FIG. 8A is a cross-sectional view illustrating a schematic configuration of a part of the pixel of FIG. 7, FIG. 8B is a diagram illustrating a potential distribution of the configuration of FIG. 8A in the first read operation, and FIG. 8C is a diagram illustrating a potential distribution of the configuration of FIG. 8A in the second read operation;

FIG. 9 is a circuit diagram illustrating an exemplary pixel configuration of 2×4 pixels in a 4-pixel 1-cell configuration of a solid-state imaging device according to a fourth embodiment;

FIG. 10A is a timing chart illustrating voltage waveforms of respective components when a pixel of FIG. 9 performs the first read operation, and FIG. 10B is a timing chart illustrating voltage waveforms of respective components when the pixel of FIG. 9 performs the second read operation;

FIG. 11A is a cross-sectional view illustrating a schematic configuration a part of the pixel of FIG. 9, FIG. 11B is a diagram illustrating a potential distribution of the configuration of FIG. 11A in the first read operation, and FIG. 11C is a diagram illustrating a potential distribution of the configuration of FIG. 11A in the second read operation;

FIG. 12A is a timing chart illustrating voltage waveforms of the respective components when the pixel of FIG. 9 performs a third read operation, and FIG. 12B is a timing chart illustrating voltage waveforms of the respective components when the pixel of FIG. 9 performs a fourth read operation.

FIG. 13A is a cross-sectional view illustrating a schematic configuration of a part of the pixel of FIG. 9, FIG. 13B is a diagram illustrating a potential distribution of the configuration of FIG. 13A in the third read operation, and FIG. 13C is a diagram illustrating a potential distribution of the configuration of FIG. 13A in the fourth read operation;

FIG. 14 is a plane view illustrating a layout configuration of the pixel of FIG. 9;

FIG. 15 is a circuit diagram illustrating an exemplary pixel configuration of 2×4 pixels in a 4-pixel 1-cell configuration of a solid-state imaging device according to a fifth embodiment;

FIG. 16A is a cross-sectional view illustrating a schematic configuration of a part of the pixel of FIG. 15, FIG. 16B is a diagram illustrating a potential distribution of the configuration of FIG. 16A in the first read operation, and FIG. 16C is a diagram illustrating a potential distribution of the configuration of FIG. 16A in the second read operation;

FIG. 17A is a cross-sectional view illustrating a schematic configuration of a part of the pixel of FIG. 15, FIG. 17B is a diagram illustrating a potential distribution of the configuration of FIG. 17A in the third read operation, and FIG. 17C is a diagram illustrating a potential distribution of the configuration of FIG. 17A in the fourth read operation;

FIG. 18 is a plane view illustrating a layout configuration of the pixel of FIG. 15;

FIG. 19A is a circuit diagram illustrating an exemplary configuration of a division transistor applied to a solid-state imaging device according to a sixth embodiment, and FIG. 19B is a plane view illustrating an exemplary layout configuration of the division transistor of FIG. 19A;

FIG. 20A is a circuit diagram illustrating an exemplary configuration of a division transistor applied to a solid-state imaging device according to a seventh embodiment, and FIG. 20B is a plane view illustrating an exemplary layout configuration of the division transistor of FIG. 20A; and

FIG. 21 is a block diagram illustrating a schematic configuration of a digital camera to which a solid-state imaging device is applied to an eighth embodiment.

### DETAILED DESCRIPTION

In general, according to one embodiment, a pixel of a solid-state imaging device includes a photo diode that generates charges by photoelectric conversion, a voltage converting unit that converts the charges generated by the photo diode into a voltage, a read transistor that reads signal charges generated by the photo diode out to the voltage converting unit, an amplifying transistor that amplifies the signal voltage converted by the voltage converting unit, and a reset transistor that resets the voltage converting unit, and the voltage converting unit includes a first voltage converting unit at the read transistor side, a second voltage converting unit at the amplifying transistor side, and a first transistor disposed between the first voltage converting unit and the second voltage converting unit.

Hereinafter, exemplary embodiments of a solid-state imaging device will be described below in detail with reference to the accompanying drawings. The present invention is not limited to the following embodiments.

### First Embodiment

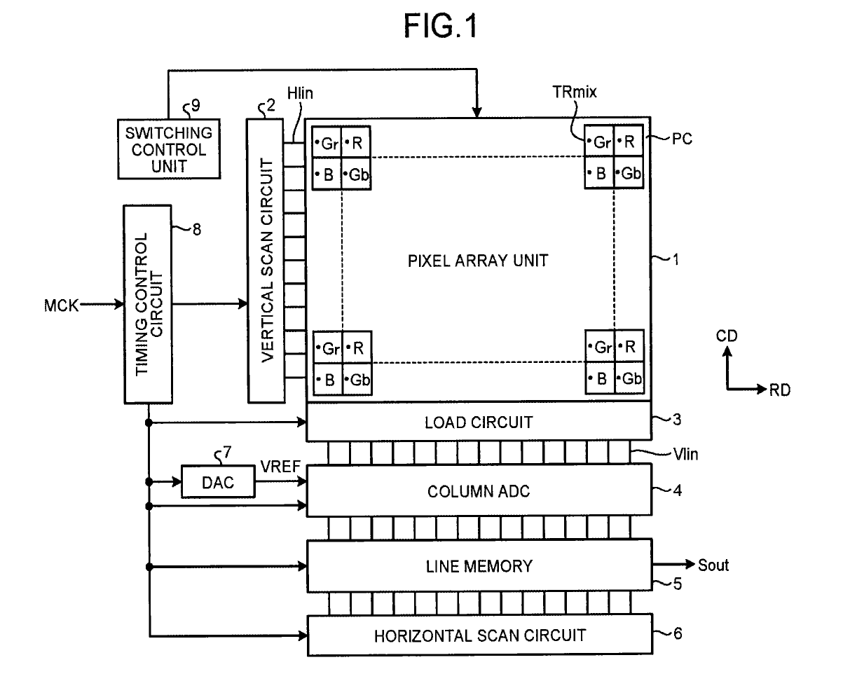

FIG. 1 is a block diagram illustrating a schematic configuration of a solid-state imaging device according to a first embodiment.

Referring to FIG. 1, a solid-state imaging device is provided with a pixel array unit 1. In the pixel array unit 1, pixels PC each of which accumulates charges obtained by photoelectric conversion are arranged in the form of an m×n matrix (m is a positive integer, and n is a positive integer) in which m pixels are arranged in a row direction RD, and n pixels are arranged in a column direction CD. In the pixel array unit 1, horizontal control lines Hlin used to control reading of the pixels PC are disposed in the row direction RD, and vertical signal lines Vlin used to transfer signals read from the pixels PC are disposed in the column direction CD. The pixel PC may configure the Bayer array including two green pixels Gr and Gb, one red pixel R, and one blue pixel B. The pixel array unit 1 is further provided with a division transistor TRmix divides a voltage converting unit that converts the charges generated by the pixels PC into a voltage into first and second voltage converting units having different potentials. The division transistor TRmix may be disposed for each pixel PC. Here, the division transistor TRmix can divide the capacity of the first voltage converting unit and the capacity of the second voltage converting unit by causing the potential of the first voltage converting unit to be different from the potential of the second voltage converting unit. At this time, the division transistor TRmix can change the conversion gain of the voltage converting unit by dividing the voltage converting unit that converts the charges generated by the pixels PC into a voltage.

The solid-state imaging device is further provided with a vertical scan circuit 2 that scans the pixels PC of the reading target in the vertical direction, a load circuit 3 that performs a source follower operation with the pixels PC and reads pixel signals from the pixels PC to the vertical signal line Vlin in units of columns, a column ADC circuit 4 that performs a CDS process for extracting only signal components of the pixels PC and performs conversion into a digital signal, a line memory 5 that stores the signal components of the pixels PC detected by the column ADC circuit 4 in units of columns, a horizontal scan circuit 6 that scans the pixels PC of the reading target in the horizontal direction, a reference voltage generating circuit 7 that outputs a reference voltage VREF to the column ADC circuit 4, a timing control circuit 8 that controls reading timings and accumulation timings of the pixels PC, and a switching control unit 9 that performs switching control on the division transistor TRmix. A master clock MCK is input to the timing control circuit 8. A ramp wave may be used as the reference voltage VREF. At the time of low luminance shooting, the switching control unit 9 can increase the conversion gain by dividing the voltage converting unit through the division transistor TRmix. At the time of high luminance shooting, the switching control unit 9 can increase the saturation electron number by causing the voltage converting unit not to be divided through the division transistor TRmix. The division transistor TRmix may be automatically switched based on an external luminance measurement result or may be arbitrarily switched by the user. The division transistor TRmix may be controlled such that all division transistors are simultaneously controlled or such that division transistors are controlled in units of horizontal control lines Hlin in synchronization with the vertical scan circuit 2.

The vertical scan circuit 2 scans the pixels PC in the vertical direction in units of lines, and thus the pixels PC are selected in the row direction RD. The load circuit 3 performs the source follower operation with the pixels PC in units of columns, and thus the pixel signals read from the pixels PC are transferred to the column ADC circuit 4 via the vertical signal line Vlin. In the reference voltage generating circuit 7, the ramp wave is set as the reference voltage VREF and transferred to the column ADC circuit 4. The column ADC circuit 4 performs conversion into a digital signal by performing a clock count operation until a signal level and a reset level read from the pixel PC match levels of the ramp wave. At this time, a difference between the signal level and the reset level is obtained, and thus the signal component of each pixel PC is detected through the CDS and output via the line memory 5 as the output signal Sout.

Here, when the capacity of the voltage converting unit is divided, it is possible to reduce the capacity of the voltage converting unit that converts charges accumulated in the pixel PC into a voltage to be smaller than when the capacity of the voltage converting unit is not divided, and thus it is possible to improve an SN ratio. Meanwhile, when the capacity of the voltage converting unit is not divided, it is possible to increase the saturation electron number of the voltage converting unit to be larger than when the capacity of the voltage converting unit is divided, and thus it is possible to increase the dynamic range.

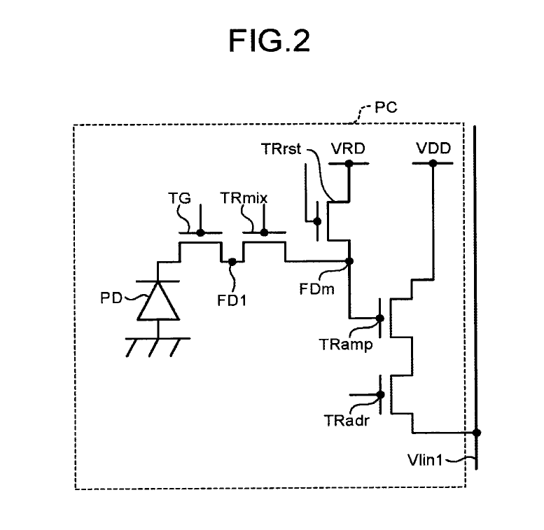

FIG. 2 is a circuit diagram illustrating an exemplary pixel configuration of the solid-state imaging device of FIG. 1.

Referring to FIG. 2, the pixel PC is provided with a photo diode PD, a row selecting transistor TRadr, an amplifying transistor TRamp, a reset transistor TRrst, and a read transistor TG. A floating diffusion FD1 is formed at the read transistor TG side as a first voltage converting unit, and a floating diffusion FDm is formed at the amplifying transistor TRamp side as the second voltage converting unit. The division transistor TRmix is disposed between the floating diffusions FD1 and FDm.

Then, the photo diode PD is connected to the floating diffusion FD1 via the read transistor TG. A gate of the amplifying transistor TRamp is connected to the floating diffusion FDm, a source of the amplifying transistor TRamp is connected to the vertical signal line Vlin1 via the row selecting transistor TRadr, a drain of the amplifying transistor TRamp is connected to a power potential VDD. The floating diffusion FDm is connected to a power potential VRD via the reset transistor TRrst. A drain of the division transistor TRmix is connected to the floating diffusion FD1, and a source of the division transistor TRmix is connected to the floating diffusion FDm. The power potential VDD and the power potential VRD may be mutually connected with each other. The row selecting transistor TRadr may be disposed between the amplifying transistor TRamp and the power potential VDD. Further, the row selecting transistor TRadr may be omitted.

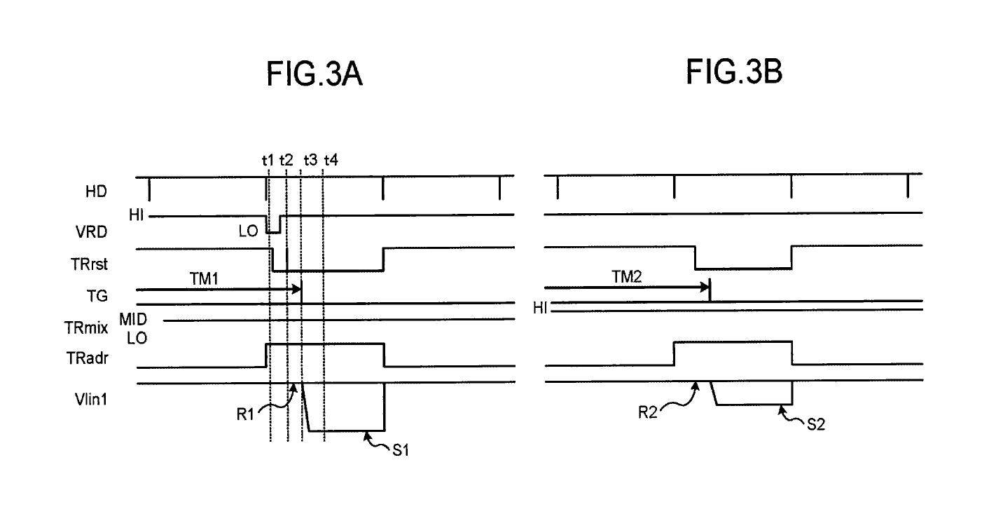

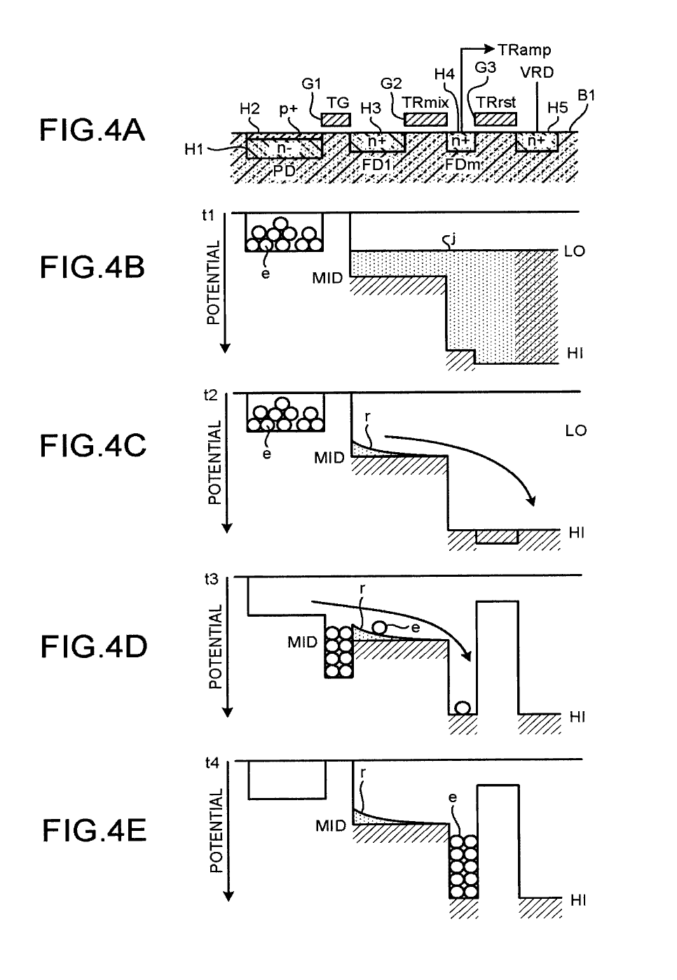

FIG. 3A is a timing chart illustrating voltage waveforms of the respective components when the pixel of FIG. 2 performs a first read operation (a high conversion gain), FIG. 3B is a timing chart illustrating voltage waveforms of the respective components when the pixel of FIG. 2 performs a second read operation (a low conversion gain), FIG. 4A is a cross-sectional view illustrating a schematic configuration a part of the pixel of FIG. 2, and FIGS. 4B to 4E are diagrams illustrating a potential distribution from a time t1 to a time t4 of FIG. 3A in the configuration of FIG. 4A. FIG. 4A illustrates the photo diode PD, the floating diffusions FD1 and FDm, the division transistor TRmix, the reset transistor TRrst, and the read transistor TG of FIG. 2.

In FIG. 4A, diffusion layers H1 to H5 are formed in a semiconductor layer B1. The diffusion layer H2 is stacked on the diffusion layer H1, and the diffusion layers H1 and H3 to H5 are separated from one another. The semiconductor layer B1 may be set to a p type, the diffusion layer H1 may be set to an n⁻ type, the diffusion layer H2 may be set to a n⁺ type, and the diffusion layers H3 to H5 may be set to an n⁺ type. A gate electrode G1 is arranged between the diffusion layers H2 and H3, a gate electrode G2 is arranged between the diffusion layers H3 and H4, and a gate electrode G3 is arranged between the diffusion layers H4 and H5. The diffusion layers H1 and H2 may be used for the photo diode PD. The diffusion layer H3 may be used for the floating diffusion FD1. The diffusion layer H4 may be used for the floating diffusion FDm. The gate electrode G1 may be used for the read transistor TG. The gate electrode G2 may be used for the division transistor TRmix. The gate electrode G3 may be used for the reset transistor TRrst.

Meanwhile, in FIG. 3A, in the first read operation, the gate potential of the division transistor TRmix is set to an intermediate potential MID between a low level LO and a high level HI, and thus the potential of the floating diffusion FDm is set to be deeper than the potential of the floating diffusion FD1. Here, as the potential of the floating diffusion FDm is set to be deeper than the potential of the floating diffusion FD1, it is possible to separate the capacity of the floating diffusion FDm from the capacity of the floating diffusion FD1 and the capacity of the division transistor TRmix.

Then, when the row selecting transistor TRadr is turned off, the amplifying transistor TRamp does not perform the source follower operation and thus outputs no signal to the vertical signal line Vlin1. Here, if the reset transistor TRrst and the read transistor TG are turned on when the power potential VRD is at the high level HI, the charges accumulated in the photo diode PD are discharged to the floating diffusions FD1 and FDm. Then, the charges are discharged to the power potential VRD via the reset transistor TRrst. When the read transistor TG is turned off after the charges accumulated in the photo diode PD are discharged to the power potential VRD, the photo diode PD starts to accumulate signal charges.

Then, if the power potential VRD transitions to the low level LO in a state in which the reset transistor TRrst is turned on, charges j are injected into the floating diffusions FD1 and FDm (t1) as illustrated in FIG. 4B. Then, as the reset transistor TRrst is turned off, the charges j are isolated in the floating diffusions FD1 and FDm, and then the power potential VRD transitions to the high level HI.

Then, the reset transistor TRrst is turned on, the charges j are discharged to the power potential VRD. At this time, since the charges j are imperfectly transferred in the floating diffusion FD1, residual charges r remain in the floating diffusion FD1 as illustrated in FIG. 4C. Further, the residual charges r work as bias charges, and thus surplus charges generated due to a leakage current or the like are transferred from the floating diffusion FD1 to the floating diffusion FDm (t2).

Then, when the row selecting transistor TRadr is turned on, the power potential VDD is applied to the drain of the amplifying transistor TRamp, and thus the amplifying transistor TRamp performs the source follower operation. Then, as a voltage according to a reset level R1 of the floating diffusion FDm is applied to the gate of the amplifying transistor TRamp, the voltage of the vertical signal line Vlin1 follows the gate voltage of the amplifying transistor TRamp, and thus the pixel signal of the reset level R1 is output to the column ADC circuit 4 via the vertical signal line Vlin1.

Then, when the read transistor TG is turned on, the charges e accumulated in the photo diode PD are transferred to the floating diffusions FD1 and FDm as illustrated in FIG. 4D (t3). Then, as the read transistor TG is turned off, the residual charges r works as the bias charges, and the charges e are transferred from the floating diffusion FD1 to the floating diffusion FDm as illustrated in FIG. 4E, (t4).

Then, as a voltage according to a signal level S1 of the floating diffusion FDm is applied to the gate of the amplifying transistor TRamp, the voltage of the vertical signal line Vlin1 follows the gate voltage of the amplifying transistor TRamp, and thus the pixel signal of the signal level S1 is output to the column ADC circuit 4 via the vertical signal line Vlin1. Then, a difference between the pixel signal of the signal level S1 and the pixel signal of the reset level R1 is obtained, and thus the signal component according to the charges e accumulated in the photo diode PD is detected. At this time, the accumulation period of time of the photo diode PD is TM1.

Meanwhile, in FIG. 3B, in the second read operation, the gate potential of the division transistor TRmix is set to the high level HI, and thus the floating diffusions FD1 and FDm are set to have the same potential. The power potential VRD is set to the high level HI. Here, as the floating diffusions FD1 and FDm are set to have the same potential, it is possible to combine the capacities of the floating diffusions FD1 and FDm.

Then, when the row selecting transistor TRadr is turned off, the amplifying transistor TRamp does not perform the source follower operation, and thus no signal is output to the vertical signal line Vlin1. Here, when the reset transistor TRrst and the read transistor TG are turned on, the charges accumulated in the photo diode PD are discharged to the floating diffusions FD1 and FDm. Then, the charges are discharged to the power potential VRD via the reset transistor TRrst. When the read transistor TG is turned off after the charges accumulated in the photo diode PD are discharged to the power potential VRD, the photo diode PD starts to accumulate signal charges.

Then, when the row selecting transistor TRadr is turned on directly after the reset transistor TRrst transitions from the on state to the off state, the power potential VDD is applied to the drain of the amplifying transistor TRamp, and thus the amplifying transistor TRamp performs the source follower operation. Then, when a voltage according to a reset level R2 of the floating diffusions FD1 and FDm is applied to the gate of the amplifying transistor TRamp, and the voltage of the vertical signal line Vlin1 follows the gate voltage of the amplifying transistor TRamp, the pixel signal of the reset level R2 is output to the column ADC circuit 4 via the vertical signal line Vlin1.

Then, when the read transistor TG is turned on, the charges e accumulated in the photo diode PD are transferred to the floating diffusions FD1 and FDm. Then, as a voltage according to a signal level S2 of the floating diffusions FD1 and FDm is applied to the gate of the amplifying transistor TRamp, the voltage of the vertical signal line Vlin1 follows the gate voltage of the amplifying transistor TRamp, and thus the pixel signal of the signal level S2 is output to the column ADC circuit 4 via the vertical signal line Vlin1. Then, a difference between the pixel signal of the signal level S2 and the pixel signal of the reset level R2 is obtained, and thus a signal component according to the charges accumulated in the photo diode PD is detected. At this time, the accumulation period of time of the photo diode PD is TM2. The above operation may be performed according to the horizontal synchronous signal HD.

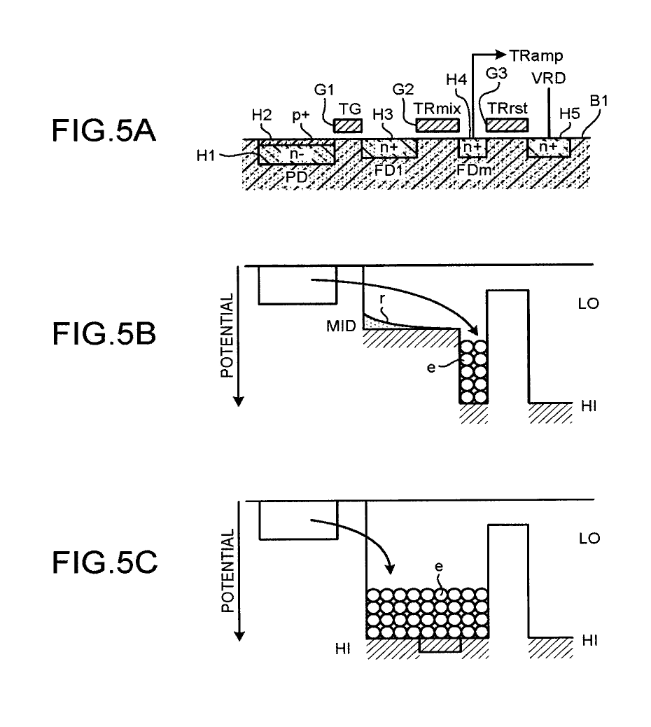

FIG. 5A is a cross-sectional view illustrating a schematic configuration of a part of the pixel of FIG. 2, FIG. 5B is a diagram illustrating a potential distribution of the configuration of FIG. 5A in the first read operation, and FIG. 5C is a diagram illustrating a potential distribution of the configuration of FIG. 5A in the second read operation.

In FIG. 5B, in the first read operation, it is possible to separate the floating diffusions FD1 and FDm from each other through the division transistor TRmix, and it is possible to reduce the capacity of the voltage converting unit that converts charges accumulated in the pixel PC into a voltage. Thus, it is possible to increase the conversion gain when the signal component is detected, and it is possible to improve an SN ratio.

In FIG. 5C, in the second read operation, it is possible to combine the floating diffusions FD1 and FDm through the division transistor TRmix, and it is possible to increase the capacity of the voltage converting unit that converts charges accumulated in the pixel PC into a voltage. Thus, it is possible to increase the saturation electron number when the signal component is detected, and it is possible to improve the dynamic range.

### Second Embodiment

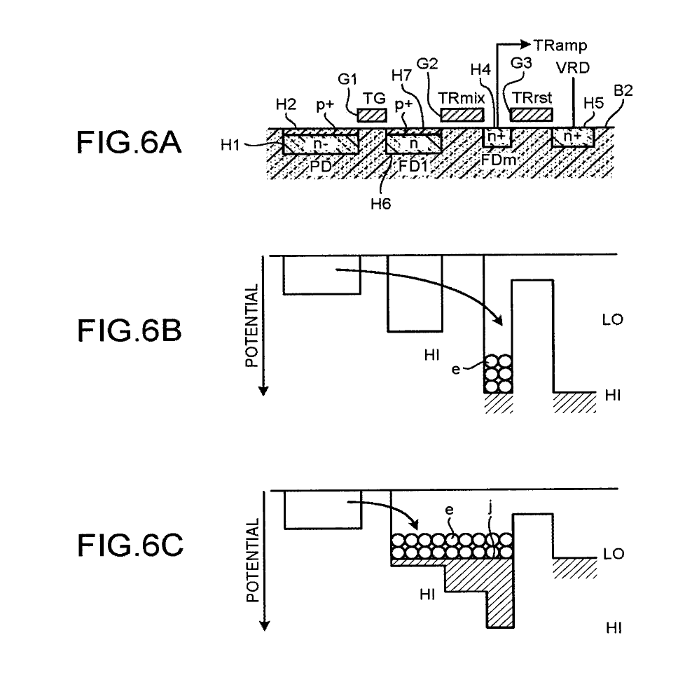

FIG. 6A is a cross-sectional view illustrating a schematic configuration of a pixel of a solid-state imaging device according to a second embodiment, FIG. 6B is a diagram illustrating a potential distribution of the configuration of FIG. 6A in the first read operation, and FIG. 6C is a diagram illustrating a potential distribution of the configuration of FIG. 6A in the second read operation.

In the configuration of FIG. 6A, the diffusion layers H6 and H7 are disposed in a semiconductor layer B2 other than the diffusion layer H3 of FIG. 4A. The diffusion layer H7 is stacked-on the diffusion layer H6. The diffusion layer H6 may be set to an n type. The diffusion layer H7 may be set to a p⁺ type. The diffusion layers H6 and H7 may be used for the floating diffusion FD1. The potential of the floating diffusion FD1 may be deeper than the potential of the photo diode PD.

Here, in the first read operation, as the diffusion layer H7 is stacked on the diffusion layer H6, channel potential of the division transistor TRmix can be shallower than the potential of the floating diffusion FD1. Thus, the charges e can be completely transferred without using the residual charges r of FIG. 5B as the bias charges. For example, when the charges e are transferred from the floating diffusion FD1 to the floating diffusion FDm, the gate potential of the division transistor TRmix is set to the high level HI, and as illustrated in FIG. 6B, when the charges e of the floating diffusion FDm are detected, the gate potential of the division transistor TRmix is set to the low level LO, and thus it is possible to improve the conversion gain while completely transferring the charges e.

Meanwhile, in the second read operation, as the power potential VRD is set to the low level LO, the gate potential of the division transistor TRmix is set to the high level HI, and the reset transistor TRrst is on, the charges j are injected into the floating diffusions FD1 and FDm. Then, as illustrated in FIG. 6C, the reset transistor TRrst is turned off, and then the charges e can be read out to the floating diffusions FD1 and FDm and the channel area of the division transistor TRmix. Thus, it is possible to increase the capacity of the voltage converting unit that converts the charges e into a voltage, and it is possible to increase the saturation electron number of the voltage converting unit.

### Third Embodiment

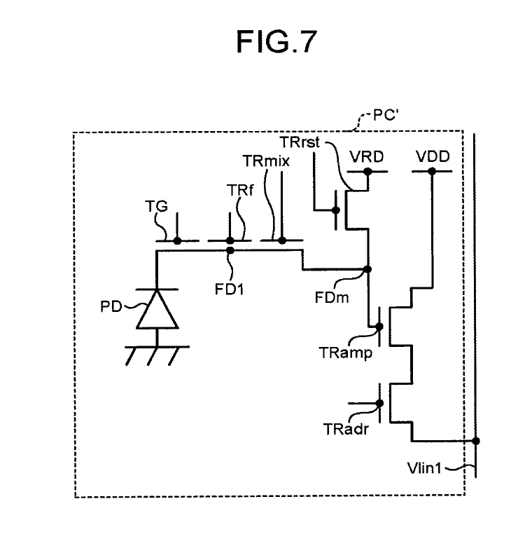

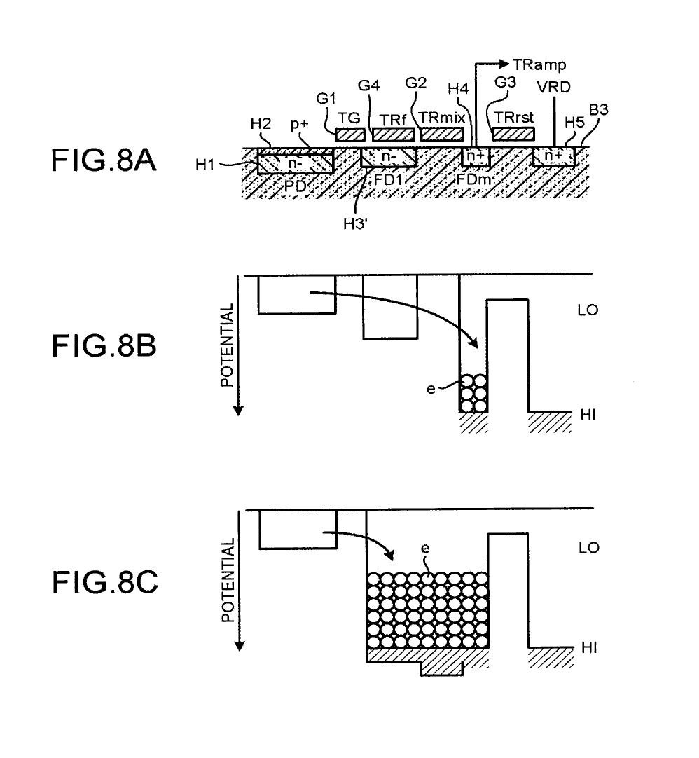

FIG. 7 is a circuit diagram illustrating an exemplary pixel configuration of a solid-state imaging device according to a third embodiment, FIG. 8A is a cross-sectional view illustrating a schematic configuration of a part of the pixel of FIG. 7, FIG. 8B is a diagram illustrating a potential distribution of the configuration of FIG. 8A in the first read operation, and FIG. 8C is a diagram illustrating a potential distribution of the configuration of FIG. 8A in the second read operation. In FIG. 7, in a pixel PC′, a transfer transistor TRf is added to the pixel PC of FIG. 2. The transfer transistor TRf is arranged between the read transistor TG and the division transistor TRmix.

In the configuration of FIG. 8A, a gate electrode G4 is added to a semiconductor layer B3 in the configuration of FIG. 5A. Further, a diffusion layer H3′ is disposed instead of the diffusion layer H3. The diffusion layer H3′ may be set to an n⁻ type. A gate electrode G4 is arranged on the diffusion layer H3′. The gate electrode G4 may be used for the transfer transistor TRf.

Here, in the first read operation, the gate potentials of the transfer transistor TRf and of the division transistor TRmix are set so that the potential sequentially gets deeper in a path of the photo diode PD→the floating diffusion FD1→the channel area of the division transistor TRmix→the floating diffusion FDm, and thus it is possible to completely transfer the charges e without using the residual charges r of FIG. 5B as the bias charges. Further, as the gate potential of the division transistor TRmix is set to the low level LO when the charges e of the floating diffusion FDm are detected as illustrated in FIG. 8B, it is possible to improve the conversion gain.

Meanwhile, in the second read operation, as the power potential VRD, the gate potential of the division transistor TRmix, and the gate potential of the transfer transistor TRf are set to the high level HI, and the reset transistor TRrst is turned on, the floating diffusions FD1 and FDm can be reset. Then, after the reset transistor TRrst is off, the charges e can be read out to the floating diffusions FD1 and FDm and the channel area of the division transistor TRmix as illustrated in FIG. 8C. Thus, it is possible to increase the capacity of the voltage converting unit that converts the charges e into a voltage, and it is possible to increase the saturation electron number of the voltage converting unit.

### Fourth Embodiment

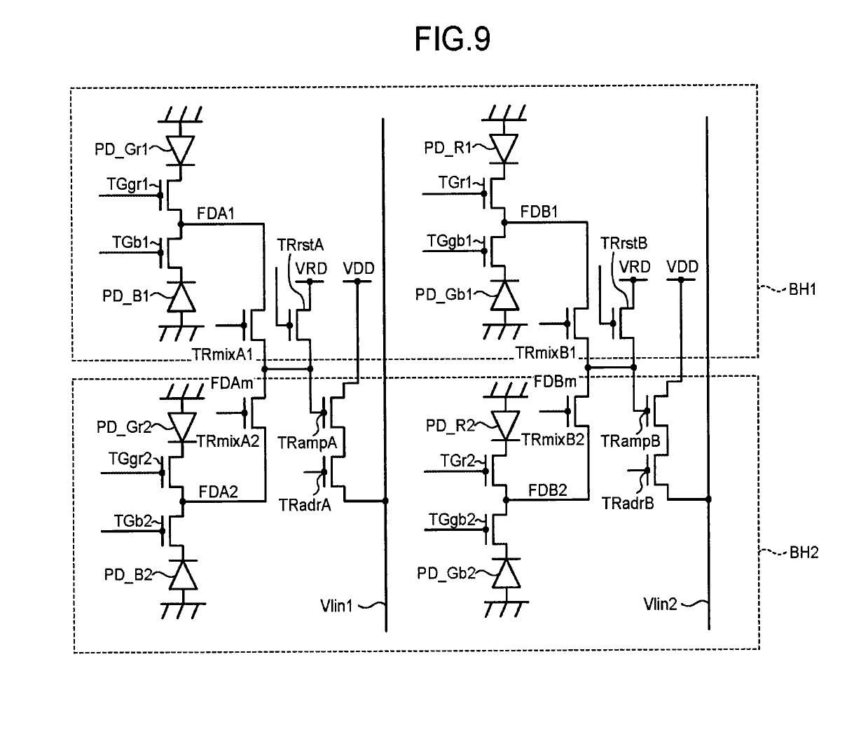

FIG. 9 is a circuit diagram illustrating an exemplary pixel configuration of 2×4 pixels in a 4-pixel 1-cell configuration of a solid-state imaging device according to a fourth embodiment.

In FIG. 9, Bayer arrays BH1 and BH2 are arranged to be adjacent in the column direction CD.

In the Bayer array BH1, a photo diode PDGr1 is disposed for a green pixel Gr, a photo diode PD_B1 is disposed for a blue pixel B, a photo diode PD_R1 is disposed for a red pixel R, and a photo diode PDGb1 is disposed for a green pixel Gb. In the Bayer array BH2, a photo diode PD_Gr2 is disposed for the green pixel Gr, a photo diode PD_B2 is disposed for the blue pixel B, a photo diode PD_R2 is disposed for the red pixel R, and a photo diode PD_Gb2 is disposed for the green pixel Gb. Further, in the Bayer array BH1, read transistors TGgr1, TGb1, TGr1, and TGgb1 and division transistors TRmixA1 and TRmixB1 are disposed, and in the Bayer array BH2, read transistors TGgr2, TGb2, TGr2, and TGgb2 and division transistors TRmixA2 and TRmixB2 are disposed. Row selecting transistors TRadrA and TRadrB, amplifying transistors TRampA and TRampB, and reset transistors TRrstA and TRrstB are disposed to be common to the Bayer arrays BH1 and BH2. A floating diffusion FDA1 is formed at a connection point of the read transistors TGgr1 and TGb1 as a first voltage converting unit, a floating diffusion FDAm is formed at a connection point of the amplifying transistor TRampA and the reset transistor TRrstA as a second voltage converting unit, and a floating diffusion FDA2 is formed at a connection point of the read transistors TGgr2 and TGb2 as a third voltage converting unit. A floating diffusion FDB1 is formed at a connection point of the read transistors TGr1 and TGgb1 as a first voltage converting unit, a floating diffusion FDBm is formed at a connection point of the amplifying transistor TRampB and the reset transistor TRrstB as a second voltage converting unit, and a floating diffusion FDB2 is formed at a connection point of the read transistors TGr2 and TGgb2 as a third voltage converting unit.

The photo diode PDGr1 is connected to the floating diffusion FDA1 via the read transistor TGgr1, and the photo diode PD_B1 is connected to the floating diffusion FDA1 via the read transistor TGb1. The photo diode PD_Gr2 is connected to the floating diffusion FDA2 via the read transistor TGgr2, and the photo diode PD_B2 is connected to the floating diffusion FDA2 via the read transistor TGb2.

A gate of the amplifying transistor TRampA is connected to the floating diffusion FDAm, a source of the amplifying transistor TRampA is connected to the vertical signal line Vlin1 via the row selecting transistor TRadrA, and a drain of the amplifying transistor TRampA is connected to the power potential VDD. The floating diffusion FDAm is connected to the power potential VRD via the reset transistor TRrstA.

The photo diode PD_R1 is connected to the floating diffusion FDB1 via the read transistor TGr1, and the photo diode PDGb1 is connected to the floating diffusion FDB1 via the read transistor TGgb1. The photo diode PD_R2 is connected to the floating diffusion FDB2 via the read transistor TGr2, and the photo diode PD_Gb2 is connected to the floating diffusion FDB2 via the read transistor TGgb2.

A gate of the amplifying transistor TRampB is connected to the floating diffusion FDBm, a source of the amplifying transistor TRampB is connected to the vertical signal line Vlin2 via the row selecting transistor TRadrB, and a drain of the amplifying transistor TRampB is connected to the power potential VDD. The floating diffusion FDBm is connected to the power potential VRD via the reset transistor TRrstB.

The division transistor TRmixA1 is connected between the floating diffusions FDA1 and FDAm, and the division transistor TRmixA2 is connected between the floating diffusions FDA2 and FDAm.

Further, signals can be input to the gates of the row selecting transistors TRadrA and TRadrB, the reset transistors TRrstA and TRrstB, and the read transistors TGgr1, TGb1, TGr1, TGgb1, TGgr2, TGb2, TGr2, and TGgb2 via the horizontal control lines Hlin. Signals can be input from the switching control unit 9 to the gates of the division transistors TRmixA1, TRmixB1, TRmixA2, and TRmixB2.

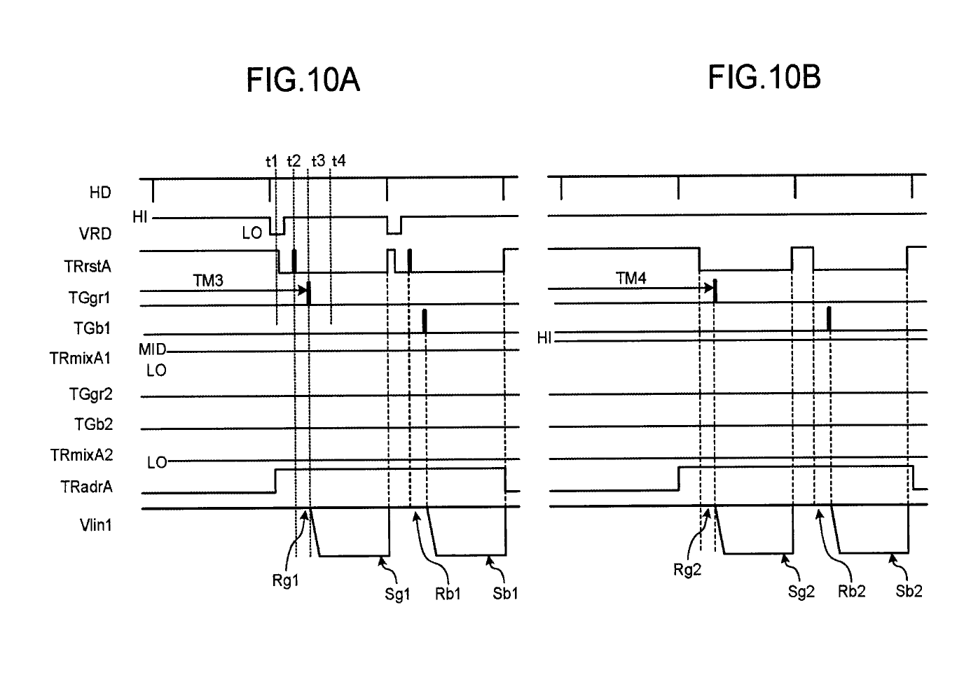

FIG. 10A is a timing chart illustrating voltage waveforms of the respective components when the pixel of FIG. 9 performs the first read operation, and FIG. 10B is a timing chart illustrating voltage waveforms of the respective components when the pixel of FIG. 9 performs the second read operation.

In FIG. 10A, in the first read operation, as the gate potential of the division transistor TRmixA1 is set to the intermediate potential MID between the low level LO and the high level HI, the potential of the floating diffusion FDAm is set to be deeper than the potential of the floating diffusion FDA1, and the capacities of the floating diffusions FDA1 and FDAm are separated from each other. Further, as the gate potential of the division transistor TRmixA2 is set to the low level LO, the floating diffusions FDA2 and FDAm are separated from each other.

Then, when the power potential VRD transitions to the low level LO in a state in which the reset transistor TRrstA is turned on, the charges j are injected into the floating diffusions FDA1 and FDAm (t1). Then, as the reset transistor TRrstA is turned off, the charges j are isolated in the floating diffusions FDA1 and FDAm, and then the power potential VRD transitions to the high level HI.

Then, when the reset transistor TRrstA is turned on, the charges j are discharged to the power potential VRD. At this time, the charges j are not completely transferred from in the floating diffusion FDA1, and thus the residual charges r remain in the floating diffusion FDA1. Then, the residual charges r work as bias charges, and surplus charges generated due to a leakage current or the like are transferred from the floating diffusion FDA1 to the floating diffusion FDAm (t2).

Then, when the row selecting transistor TRadrA is turned on, the power potential VDD is applied to the drain of the amplifying transistor TRampA, and thus the amplifying transistor TRampA performs the source follower operation. Then, as a voltage according to a reset level Rg1 of the floating diffusion FDAm is applied to the gate of the amplifying transistor TRampA, the voltage of the vertical signal line Vlin1 follows a gate voltage of the amplifying transistor TRampA, and thus the pixel signal of the reset level Rg1 is output to the column ADC circuit 4 via the vertical signal line Vlin1.

Then, when the read transistor TGgr1 is turned on, the charges e accumulated in the photo diode PD_Gr1 are transferred to the floating diffusions FDA1 and FDAm (t3). Then, the read transistor TGgr1 is turned off, and the residual charges r work as the bias charges, and thus the charges e are transferred from the floating diffusion FDA1 to the floating diffusion FDAm (t4).

Then, as a voltage according to a signal level Sg1 of the floating diffusion FDAm is applied to the gate of the amplifying transistor TRampA, the voltage of the vertical signal line Vlin1 follows the gate voltage of the amplifying transistor TRampA, and thus the pixel signal of the signal level Sg1 is output to the column ADC circuit 4 via the vertical signal line Vlin1. Then, a difference between the pixel signal of the signal level Sg1 and the pixel signal of the reset level Rg1 is obtained, and thus a signal component according to the charges e accumulated in the photo diode PD_Gr1 is detected. At this time, the accumulation period of time of the photo diode PDGr1 is TM3.

After the pixel signal of the signal level Sg1 is output to the vertical signal line Vlin1, when the reset transistor TRrstA is turned on and the power potential VRD transitions to the low level LO, the charges j are injected into the floating diffusions FDA1 and FDAm. Then, as the reset transistor TRrstA is turned off, the charges j are isolated in the floating diffusions FDA1 and FDAm, and then the power potential VRD transitions to the high level HI.

Then, when the reset transistor TRrstA is turned on, the charges j are discharged to the power potential VRD. At this time, the charges j are not completely transferred from the floating diffusion FDA1, and thus the residual charges r remain in the floating diffusion FDA1. Then, the residual charges r work as the bias charges, and thus surplus charges generated due to a leakage current or the like are transferred from the floating diffusion FDA1 to the floating diffusion FDAm.

Then, as a voltage according to a reset level Rb1 of the floating diffusion FDAm is applied to the gate of the amplifying transistor TRampA, the voltage of the vertical signal line Vlin1 follows the gate voltage of the amplifying transistor TRampA, and thus the pixel signal of the reset level Rb1 is output to the column ADC circuit 4 via the vertical signal line Vlin1.

Then, when the read transistor TGb1 is turned on, the charges e accumulated in the photo diode PD_B1 are transferred to the floating diffusions FDA1 and FDAm. Then, the read transistor TGb1 is turned off, and the residual charges r work as the bias charges, and thus the charges e are transferred from the floating diffusion FDA1 to the floating diffusion FDAm.

Then, as a voltage according to a signal level Sb1 of the floating diffusion FDAm is applied to the gate of the amplifying transistor TRampA, the voltage of the vertical signal line Vlin1 follows the gate voltage of the amplifying transistor TRampA, and thus the pixel signal of the signal level Sb1 is output to the column ADC circuit 4 via the vertical signal line Vlin1. Then, a difference between the pixel signal of the signal level Sb1 and the pixel signal of the reset level Rb1 is obtained, and thus a signal component according to the charges e accumulated in the photo diode PD_B1 is detected.

Meanwhile, in FIG. 10B, in the second read operation, as the gate potential of the division transistor TRmixA1 is set to the high level HI, the floating diffusions FDA1 and FDAm are set to have the same potential, and the capacities of the floating diffusions FDA1 and FDAm are combined. Further, as the gate potential of the division transistor TRmixA2 is set to the low level LO, the floating diffusions FDA2 and FDAm are separated from each other. The power potential VRD is set to the high level HI.

Then, if the row selecting transistor TRadrA is turned on when the reset transistor TRrstA is in the on state, the power potential VDD is applied to the drain of the amplifying transistor TRampA, and thus the amplifying transistor TRampA performs the source follower operation. Then, as a voltage according to a reset level Rg2 of the floating diffusions FDA1 and FDAm is applied to the gate of the amplifying transistor TRampA, the voltage of the vertical signal line Vlin1 follows the gate voltage of the amplifying transistor TRampA, and thus the pixel signal of the reset level Rg2 is output to the column ADC circuit 4 via the vertical signal line Vlin1.

Then, when the read transistor TGgr1 is turned on, the charges e accumulated in the photo diode PDGr1 are transferred to the floating diffusions FDA1 and FDAm. Then, as a voltage according to a signal level Sg2 of the floating diffusions FDA1 and FDAm is applied to the gate of the amplifying transistor TRampA, the voltage of the vertical signal line Vlin1 follows the gate voltage of the amplifying transistor TRampA, and thus the pixel signal of the signal level Sg2 is output to the column ADC circuit 4 via the vertical signal line Vlin1. Then, a difference between the pixel signal of the signal level Sg2 and the pixel signal of the reset level Rg2 is obtained, and thus a signal component according to the charges accumulated in the photo diode PDGr1 is detected. At this time, the accumulation period of time of the photo diode PDGr1 is TM4.

After the pixel signal of the signal level Sg2 is output to the vertical signal line Vlin1, when the reset transistor TRrstA is turned on, a voltage according to a reset level Rb2 of the floating diffusions FDA1 and FDAm is applied to the gate of the amplifying transistor TRampA, the voltage of the vertical signal line Vlin1 follows the gate voltage of the amplifying transistor TRampA, and thus the pixel signal of the reset level Rb2 is output to the column ADC circuit 4 via the vertical signal line Vlin1.

Then, when the read transistor TGb1 is turned on, the charges e accumulated in the photo diode PD_B1 are transferred to the floating diffusions FDA1 and FDAm. Then, as a voltage according to a signal level Sb2 of the floating diffusions FDA1 and FDAm is applied to the gate of the amplifying transistor TRampA, the voltage of the vertical signal line Vlin1 follows the gate voltage of the amplifying transistor TRampA, and thus the pixel signal of the signal level Sb2 is output to the column ADC circuit 4 via the vertical signal line Vlin1. Then, a difference between the pixel signal of the signal level Sb2 and the pixel signal of the reset level Rb2 is obtained, and thus a signal component according to the charges accumulated in the photo diode PD_B1 is detected.

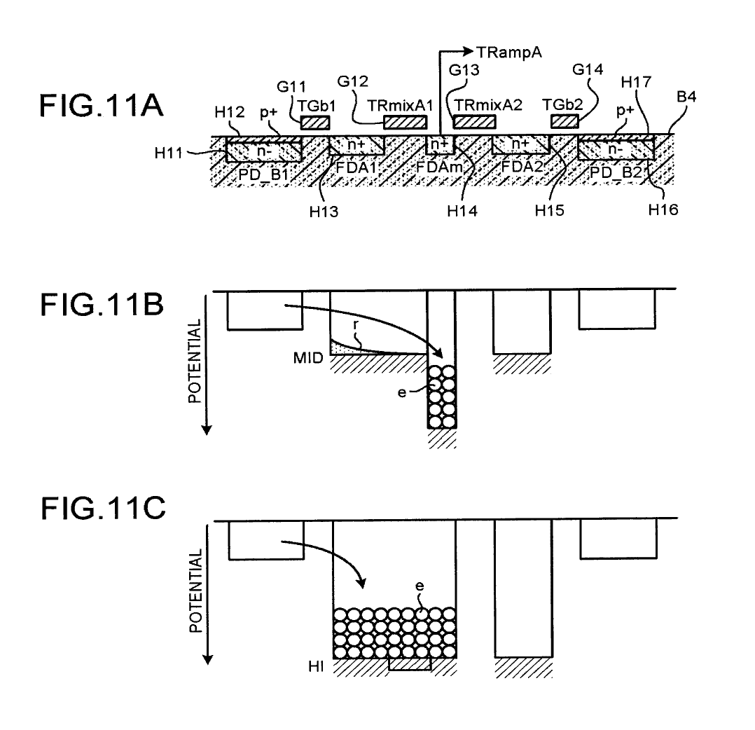

FIG. 11A is a cross-sectional view illustrating a schematic configuration a part of the pixel of FIG. 9, FIG. 11B is a diagram illustrating a potential distribution of the configuration of FIG. 11A in the first read operation, and FIG. 11C is a diagram illustrating a potential distribution of the configuration of FIG. 11A in the second read operation. FIG. 11A illustrates the photo diodes PD_B1 and PD_B2, the floating diffusions FDA1, FDA2, and FDAm, the division transistors TRmixA1 and TRmixA2, and the read transistors TGb1 and TGb2 of FIG. 9.

In FIG. 11A, diffusion layers H11 to H17 are formed in a semiconductor layer B4. The diffusion layer H12 is stacked on the diffusion layer H11, the diffusion layer H17 is stacked on the diffusion layer H16, and the diffusion layers H11 and H13 to H16 are separated from one another. The semiconductor layer B4 may be set to a p type, the diffusion layers H11 and H16 may be set to an n⁻ type, the diffusion layers H12 and H17 may be set to a p⁺ type, and the diffusion layers H13 to H15 may be set to an n⁺ type. A gate electrode G11 is arranged between the diffusion layers H12 and H13, a gate electrode G12 is arranged between the diffusion layers H13 and H14, a gate electrode G13 is arranged between the diffusion layers H14 and H15, and a gate electrode G14 is arranged between the diffusion layers H15 and H17. The diffusion layers H11 and H12 may be used for the photo diode PD_B1. The diffusion layers H16 and H17 may be used for the photo diode PD_B2. The diffusion layer H13 may be used for the floating diffusion FDA1. The diffusion layer H14 may be used fort [symbol] the floating diffusion FDAm. The diffusion layer H15 may be used fort [symbol] the floating diffusion FDA2. The gate electrode G11 may be used for the read transistor TGb1. The gate electrode G12 may be used for the division transistor TRmixA1. The gate electrode G13 may be used for the division transistor TRmixA2. The gate electrode G14 may be used for the read transistor TGb2.

In FIG. 11B, in the first read operation, it is possible to separate the capacities of the floating diffusions FDA1 and FDAm through the division transistor TRmixA1, it is possible to separate the floating diffusions FDA2 and FDAm through the division transistor TRmixA2, and it is possible to reduce the capacity of the voltage converting unit that converts charges accumulated in the pixel PC into a voltage. Thus, it is possible to increase the conversion gain when the signal component is detected, and it is possible to improve an SN ratio.

In FIG. 11C, in the second read operation, it is possible to combine the capacities of the floating diffusions FDA1 and FDAm through the division transistor TRmixA1, it is possible to separate the floating diffusions FDA2 and FDAm through the division transistor TRmixA2, and it is possible to increase the capacity of the voltage converting unit that converts charges accumulated in the pixel PC into a voltage without binning charges accumulated in the photo diodes PD_B1 and PD_B2. Thus, it is possible to increase the saturation electron number when the signal component is detected, and it is possible to improve the dynamic range.

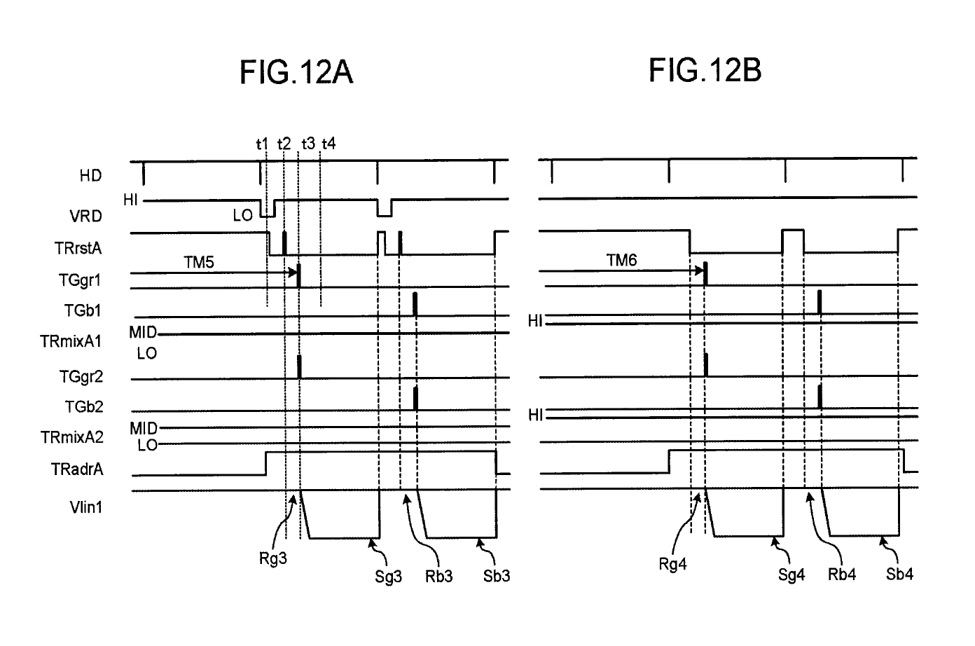

FIG. 12A is a timing chart illustrating voltage waveforms of the respective components when the pixel of FIG. 9 performs a third read operation, and FIG. 12B is a timing chart illustrating voltage waveforms of the respective components when the pixel of FIG. 9 performs a fourth read operation.

In FIG. 12A, in the third read operation, as the gate potentials of the division transistors TRmixA1 and TRmixA2 are set to the intermediate potential MID between the low level LO and the high level HI, the potential of the floating diffusion FDAm is set to be deeper than the potential of the floating diffusions FDA1 and FDA2, and the capacities of the floating diffusions FDA1 and FDA2 are separated from the capacity of the floating diffusion FDAm.

Then, when the power potential VRD transitions to the low level LO in a state in which the reset transistor TRrstA is turned on, the charges j are injected into the floating diffusions FDA1, FDA2, and FDAm. Then, the reset transistor TRrstA is turned off, and thus the charges j are isolated in the floating diffusions FDA1, FDA2, and FDAm, and then the power potential VRD transitions to the high level HI.

Then, when the reset transistor TRrstA is turned on, the charges j are discharged to the power potential VRD. At this time, since the charges j are not completely transferred from the floating diffusions FDA1 and FDA2, the residual charges r remain in the floating diffusions FDA1 and FDA2. Then, the residual charges r work as the bias charges, and thus surplus charges generated due to a leakage current or the like are transferred from the floating diffusions FDA1 and FDA2 to the floating diffusion FDAm.

Then, when the row selecting transistor TRadrA is turned on, the power potential VDD is applied to the drain of the amplifying transistor TRampA, and thus the amplifying transistor TRampA performs the source follower operation. Then, as a voltage according to a reset level Rg3 of the floating diffusion FDAm is applied to the gate of the amplifying transistor TRampA, the voltage of the vertical signal line Vlin1 follows the gate voltage of the amplifying transistor TRampA, and thus the pixel signal of the reset level Rg3 is output to the column ADC circuit 4 via the vertical signal line Vlin1.

Then, when the read transistor TGgr1, TGgr2 is turned on, the charges e accumulated in the photo diode PD_Gr1 and PD_Gr2 are transferred to the floating diffusions FDA1, FDA2, and FDAm. Then, the read transistor TGgr1, TGgr2 is turned off, the residual charges r work as the bias charges, and thus the charges e are transferred from the floating diffusions FDA1 and FDA2 to the floating diffusion FDAm.

Then, as a voltage according to a signal level Sg3 of the floating diffusion FDAm is applied to the gate of the amplifying transistor TRampA, the voltage of the vertical signal line Vlin1 follows the gate voltage of the amplifying transistor TRampA, and thus the pixel signal of the signal level Sg3 is output to the column ADC circuit 4 via the vertical signal line Vlin1. Then, a difference between the pixel signal of the signal level Sg3 and the pixel signal of the reset level Rg3 is obtained, and thus a signal component according to the charges e accumulated in the photo diode PD_Gr1 and PD_Gr2 is detected. At this time, the accumulation periods of time of the photo diodes PD_Gr1 and PD_Gr2 is TM5.

After the pixel signal of the signal level Sg3 is output to the vertical signal line Vlin1, when the reset transistor TRrstA is turned on, and the power potential VRD transitions to the low level LO, the charges j are injected into the floating diffusions FDA1, FDA2, and FDAm. Then, as the reset transistor TRrstA is turned off, the charges j are isolated in the floating diffusions FDA1, FDA2, and FDAm, and then the power potential VRD transitions to the high level HI.

Then, when the reset transistor TRrstA is turned on, the charges j are discharged to the power potential VRD. At this time, since the charges j are not completely transferred from the floating diffusions FDA1 and FDA2, the residual charges r remain in the floating diffusion FDA1. Then, the residual charges r work as the bias charges, and thus surplus charges generated due to a leakage current or the like are transferred from the floating diffusions FDA1 and FDA2 to the floating diffusion FDAm.

Then, as a voltage according to a reset level Rb3 of the floating diffusion FDAm is applied to the gate of the amplifying transistor TRampA, the voltage of the vertical signal line Vlin1 follows the gate voltage of the amplifying transistor TRampA, and thus the pixel signal of the reset level Rb3 is output to the column ADC circuit 4 via the vertical signal line Vlin1.

Then, when the read transistors TGb1 and TGb2 are turned on, the charges e accumulated in the photo diodes PD_B1 and PD_B2 are transferred to the floating diffusions FDA1, FDA2, and FDAm. Then, the read transistor TGb1, TGb2 is turned off, the residual charges r work as the bias charges, and thus the charges e are transferred from the floating diffusions FDA1 and FDA2 to the floating diffusion FDAm.

Then, as a voltage according to a signal level Sb3 of the floating diffusion FDAm is applied to the gate of the amplifying transistor TRampA, the voltage of the vertical signal line Vlin1 follows the gate voltage of the amplifying transistor TRampA, and thus the pixel signal of the signal level Sb3 is output to the column ADC circuit 4 via the vertical signal line Vlin1. Then, a difference between the pixel signal of the signal level Sb3 and the pixel signal of the reset level Rb3 is obtained, and thus a signal component according to the charges e accumulated in the photo diodes PD_B1 and PD_B2 is detected.

Meanwhile, in FIG. 12B, in the fourth read operation, as the gate potentials of the division transistors TRmixA1 and TRmixA2 are set to the high level HI, the floating diffusions FDA1, FDA2, and FDAm are set to have the same potential, and the capacities of the floating diffusions FDA1, FDA2, and FDAm are combined. The power potential VRD is set to the high level HI.

Then, if the row selecting transistor TRadrA is turned on when the reset transistor TRrstA is in the on state, the power potential VDD is applied to the drain of the amplifying transistor TRampA, and thus the amplifying transistor TRampA performs the source follower operation. Then, as a voltage according to a reset level Rg4 of the floating diffusions FDA1, FDA2, and FDAm are applied to the gate of the amplifying transistor TRampA, the voltage of the vertical signal line Vlin1 follows the gate voltage of the amplifying transistor TRampA, and thus the pixel signal of the reset level Rg4 is output to the column ADC circuit 4 via the vertical signal line Vlin1.

Then, when the read transistors TGgr1 and TGgr2 are turned on, the charges e accumulated in the photo diode PD_Gr1 and PD_Gr2 are transferred to the floating diffusions FDA1, FDA2, and FDAm. Then, as a voltage according to a signal level Sg4 of the floating diffusions FDA1, FDA2, and FDAm is applied to the gate of the amplifying transistor TRampA, the voltage of the vertical signal line Vlin1 follows the gate voltage of the amplifying transistor TRampA, and thus the pixel signal of the signal level Sg4 is output to the column ADC circuit 4 via the vertical signal line Vlin1. Then, a difference between the pixel signal of the signal level Sg4 and the pixel signal of the reset level Rg4 is obtained, and thus the a signal component according to the charges accumulated in photo diodes PD_Gr1 and PD_Gr2 is detected. At this time, the accumulation periods of time of the photo diodes PD_Gr1 and PD_Gr2 is TM6.

After the pixel signal of the signal level Sg4 is output to the vertical signal line Vlin1, when the reset transistor TRrstA is turned on, a voltage according to a reset level Rb4 of the floating diffusions FDA1, FDA2, and FDAm is applied to the gate of the amplifying transistor TRampA, the voltage of the vertical signal line Vlin1 follows the gate voltage of the amplifying transistor TRampA, and thus the pixel signal of the reset level Rb4 is output to the column ADC circuit 4 via the vertical signal line Vlin1.

Then, when the read transistors TGb1 and TGb2 are turned on, the charges e accumulated in the photo diodes PD_B1 and PD_B2 are transferred to the floating diffusions FDA1, FDA2, and FDAm. Then, as a voltage according to a signal level Sb4 of the floating diffusions FDA1, FDA2, and FDAm is applied to the gate of the amplifying transistor TRampA, the voltage of the vertical signal line Vlin1 follows the gate voltage of the amplifying transistor TRampA, and thus the pixel signal of the signal level Sb4 is output to the column ADC circuit 4 via the vertical signal line Vlin1. Then, a difference between the pixel signal of the signal level Sb4 and the pixel signal of the reset level Rb4 is obtained, and thus a signal component according to the charges accumulated in the photo diodes PD_B1 and PD_B2 is detected.

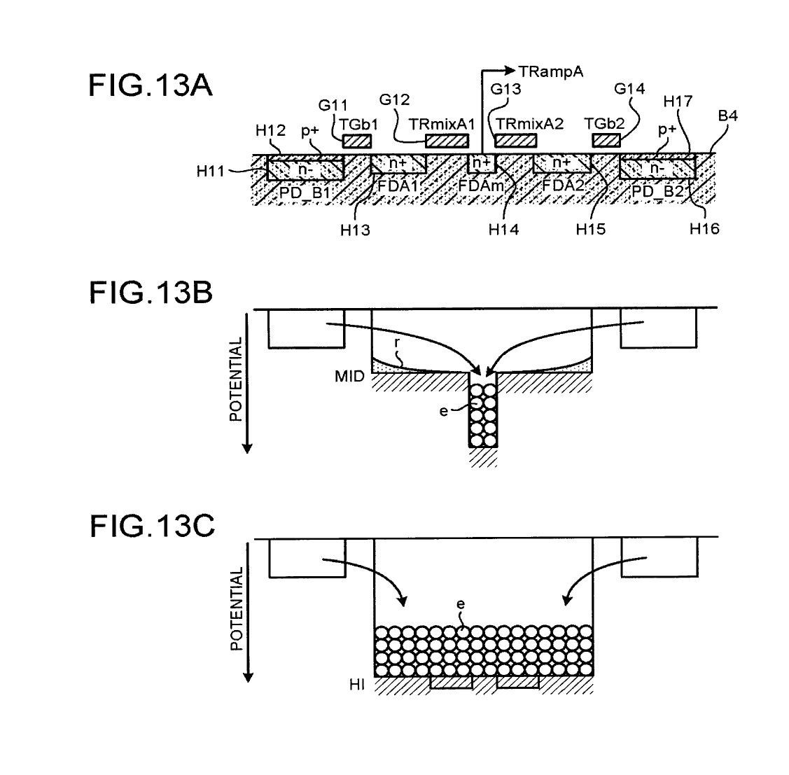

FIG. 13A is a cross-sectional view illustrating a schematic configuration of a part of the pixel of FIG. 9, FIG. 13B is a diagram illustrating a potential distribution of the configuration of FIG. 13A in the third read operation, and FIG. 13C is a diagram illustrating a potential distribution of the configuration of FIG. 13A in the fourth read operation.

In FIG. 13B, in the third read operation, it is possible to separate the capacities of the floating diffusions FDA1 and FDA2 from the capacity of the floating diffusion FDAm through the division transistors TRmixA1 and TRmixA2, and it is possible to reduce the capacity of the voltage converting unit that converts charges accumulated in the pixel PC into a voltage while binning (adding) the charges accumulated in the photo diodes PD_B1 and PD_B2. Thus, it is possible to increase the conversion gain when the signal component is detected, and it is possible to improve an SN ratio.

In FIG. 13C, in the fourth read operation, it is possible to combine the capacities of the floating diffusions FDA1, FDA2, and FDAm through the division transistors TRmixA1 and TRmixA2, and it is possible to increase the capacity of the voltage converting unit that converts charges accumulated in the pixel PC into a voltage while binning the charges accumulated in the photo diodes PD_B1 and PD_B2. Thus, it is possible to increase the saturation electron number when the signal component is detected, and it is possible to improve the dynamic range.

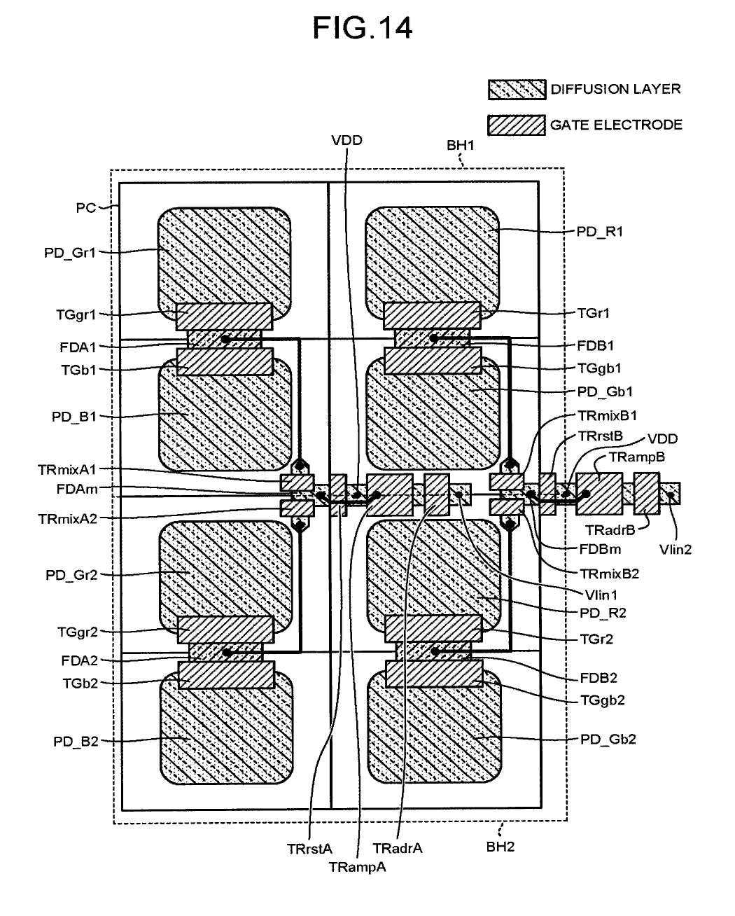

FIG. 14 is a plane view illustrating an exemplary layout configuration of the pixel of FIG. 9.

Referring to FIG. 14, the photo diode PDGr1, PD_B1, PD_R1, and PD_Gb1 are arranged in the form of a 2×2 matrix, and the photo diodes PDGr2, PD_B2, PD_R2, and PDGb2 are arranged in the form of a 2×2 matrix. The floating diffusion FDA1 is arranged between the photo diodes PD_Gr1 and PD_B1, the floating diffusion FDB1 is arranged between the photo diodes PD_R1 and PDGb1, the floating diffusion FDA2 is arranged between the photo diodes PDGr2 and PD_B2, and the floating diffusion FDB2 is arranged between the photo diodes PD_R2 and PD_Gb2.

The read transistor TGgr1 is arranged between the photo diode PD_Gr1 and the floating diffusion FDA1, the read transistor TGb1 is arranged between the photo diode PD_B1 and the floating diffusion FDA1, the read transistor TGr1 is arranged between the photo diode PD_R1 and the floating diffusion FDB1, and the read transistor TGgb1 is arranged between the photo diode PD_Gb1 and the floating diffusion FDB1. The read transistor TGgr2 is arranged between the photo diode PD_Gr2 and the floating diffusion FDA2, the read transistor TGb2 is arranged between the photo diode PD_B2 and the floating diffusion FDA2, the read transistor TGr2 is arranged between the photo diode PD_R2 and the floating diffusion FDB2, and the read transistor TGgb2 is arranged between the photo diode PD_Gb2 and the floating diffusion FDB2.

Between the Bayer arrays BH1 and BH2, the division transistors TRmixA1 and TRmixA2 are arranged to be adjacent in the column direction CD. The reset transistor TRrstA is arranged to be adjacent to the division transistors TRmixA1 and TRmixA2 in the row direction RD, the amplifying transistor TRampA is arranged to be adjacent to the reset transistor TRrstA in the row direction RD, and the selecting transistor TRadrA is arranged to be adjacent to the amplifying transistor TRampA in the row direction RD.

Further, between the Bayer arrays BH1 and BH2, the division transistors TRmixB1 and TRmixB2 are arranged to be adjacent in the column direction CD. The reset transistor TRrstB is arranged to be adjacent to the division transistors TRmixB1 and TRmixB2 in the row direction RD, the amplifying transistor TRampB is arranged to be adjacent to the reset transistor TRrstB in the row direction RD, and the selecting transistor TRadrB is arranged to be adjacent to the amplifying transistor TRampB in the row direction RD.

As a result, it is possible to arrange the division transistors TRmixA1 and TRmixA2 to be adjacent in the column direction CD and arrange the division transistors TRmixB1 and TRmixB2 to be adjacent in the column direction CD without undermining the uniform pixel arrangement in the Bayer arrays BH1 and BH2. Thus, it is possible to reduce the capacities of the floating diffusion FDAm, FDBm, and it is possible to improve the conversion gain.

### Fifth Embodiment

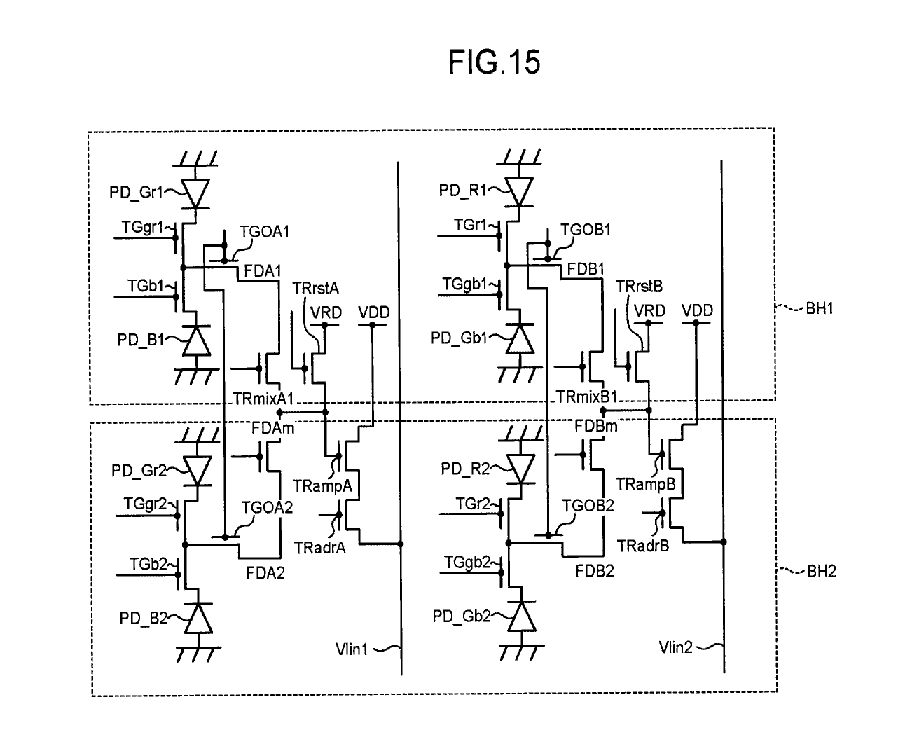

FIG. 15 is a circuit diagram illustrating an exemplary pixel configuration of 2×4 pixels in a 4-pixel 1-cell configuration of a solid-state imaging device according to a fifth embodiment.

Referring to FIG. 15, in the solid-state imaging device, transfer transistors TGOA1, TGOA2, TGOB1, and TGOB2 are added to the configuration of FIG. 9. Read transistors TGgr1 and TGb1 are connected to a floating diffusion FDA1 via the transfer transistor TGOA1. Read transistors TGgr2 and TGb2 are connected to a floating diffusion FDA2 via the transfer transistor TGOA2. Read transistors TGr1 and TGgb1 are connected to a floating diffusion FDB1 via the transfer transistor TGOB1. Read transistors TGr2 and TGgb2 are connected to a floating diffusion FDB2 via the transfer transistor TGOB2.

The solid-state imaging device of FIG. 15 operates, similarly to those of FIG. 10A, FIG. 10B, FIG. 12A, and FIG. 12B. Here, when the charges e are read through the read transistors TGgr1, TGb1, TGgr2, TGb2, TGr1, TGgb1, TGr2, and TGgb2, the transfer transistors TGOA1, TGOA2, TGOB1, and TGOB2 can set their gate potential to the intermediate potential MID between the low level LO and the high level HI. Thus, when the charges e are read through the read transistors TGgr1, TGb1, TGgr2, TGb2, TGr1, TGgb1, TGr2, and TGgb2, it is possible to reduce a variation in a charge amount of the residual charges r of the floating diffusions FDA1 and FDA2 generated when the read transistors TGgr1, TGb1, TGgr2, TGb2, TGr1, TGgb1, TGr2, and TGgb2 perform a pulse operation, and it is possible to reduce random noise.

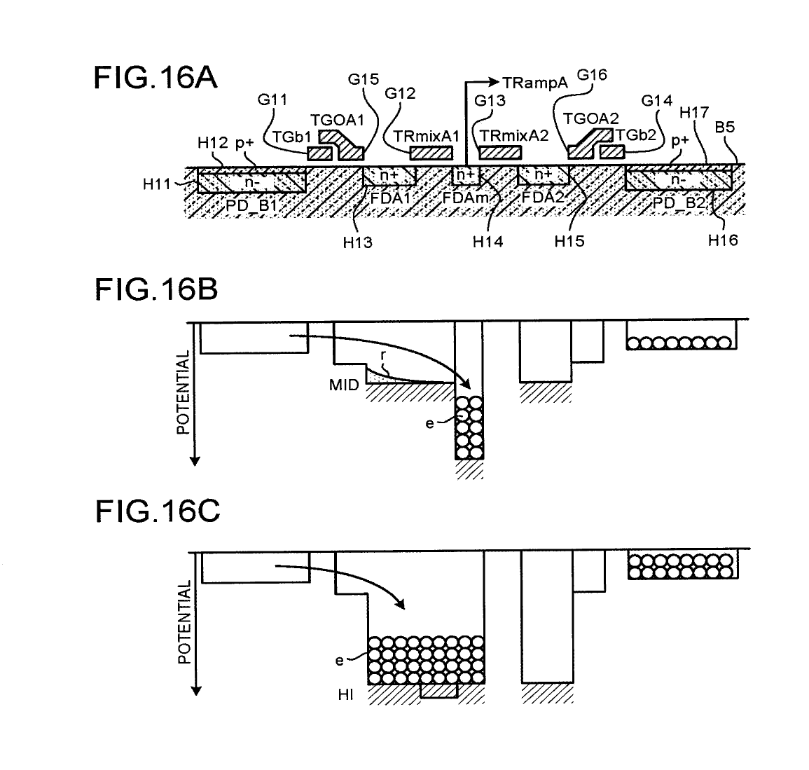

FIG. 16A is a cross-sectional view illustrating a schematic configuration of a part of the pixel of FIG. 15, FIG. 16B is a diagram illustrating a potential distribution of the configuration of FIG. 16A in the first read operation, and FIG. 16C is a diagram illustrating a potential distribution of the configuration of FIG. 16A in the second read operation.

Referring to FIG. 16A, in a semiconductor layer B5, the gate electrodes G15 and G16 are added to the configuration of FIG. 11A. The gate electrode G15 is arranged between the gate electrode G11 and the diffusion layer H13, and the gate electrode G16 is arranged between the gate electrode G14 and the diffusion layer H15. As a material of the gate electrodes G15 and G16, for example, a poly crystalline silicon may be used. The gate electrode G15 may be used for the transfer transistor TGOA1. The gate electrode G16 may be used for the transfer transistor TGOA2.

In FIG. 16B, in the first read operation, it is possible to separate the capacities of the floating diffusions FDA1 and FDAm through the division transistor TRmixA1, it is possible to separate the floating diffusions FDA2 and FDAm through the division transistor TRmixA2, and it is possible to reduce the capacity of the voltage converting unit that converts charges accumulated in the pixel PC into a voltage. At this time, the gate potential of the transfer transistor TGOA1 is set to the intermediate potential MID between the low level LO and the high level HI, and thus it is possible to reduce a variation in the charge amount of the residual charges r of the floating diffusion FDA1, and it is possible to reduce random noise.

In FIG. 16C, in the second read operation, it is possible to combine the capacities of the floating diffusions FDA1 and FDAm through the division transistor TRmixA1, it is possible to separate the floating diffusions FDA2 and FDAm through the division transistor TRmixA2, and it is possible to increase the capacity of the voltage converting unit that converts charges accumulated in the pixel PC into a voltage without binning the charges accumulated in the photo diodes PD_B1 and PD_B2.

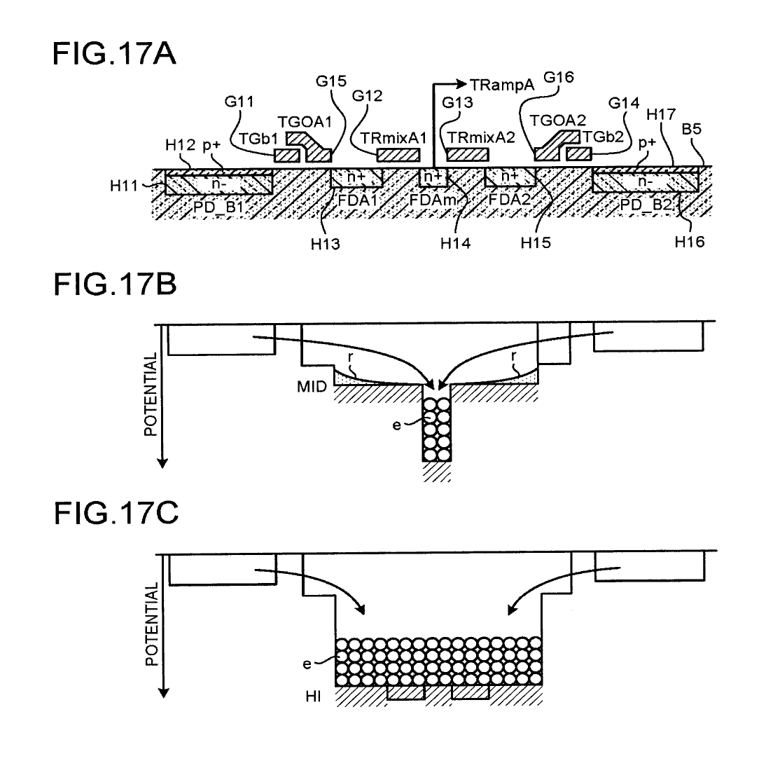

FIG. 17A is a cross-sectional view illustrating a schematic configuration of a part of the pixel of FIG. 15, FIG. 17B is a diagram illustrating a potential distribution of the configuration of FIG. 17A in the third read operation, and FIG. 17C is a diagram illustrating a potential distribution of the configuration of FIG. 17A in the fourth read operation.

In FIG. 17B, in the third read operation, it is possible to separate the capacities of the floating diffusions FDA1 and FDA2 from the capacity of the floating diffusion FDAm through the division transistors TRmixA1 and TRmixA2, and it is possible to reduce the capacity of the voltage converting unit that converts charges accumulated in the pixel PC into a voltage while binning the charges accumulated in the photo diodes PD_B1 and PD_B2. At this time, the gate potentials of the transfer transistors TGOA1 and TGOA2 are set to the intermediate potential MID between the low level LO and the high level HI, and thus it is possible to reduce a variation in a charge amount of the residual charges r of the floating diffusions FDA1 and FDA2, and it is possible to reduce random noise.

In FIG. 17C, in the fourth read operation, it is possible to combine the capacities of the floating diffusions FDA1, FDA2, and FDAm through the division transistors TRmixA1 and TRmixA2, and it is possible to increase the capacity of the voltage converting unit that converts charges accumulated in the pixel PC into a voltage while binning the charges accumulated in the photo diodes PD_B1 and PD_B2.

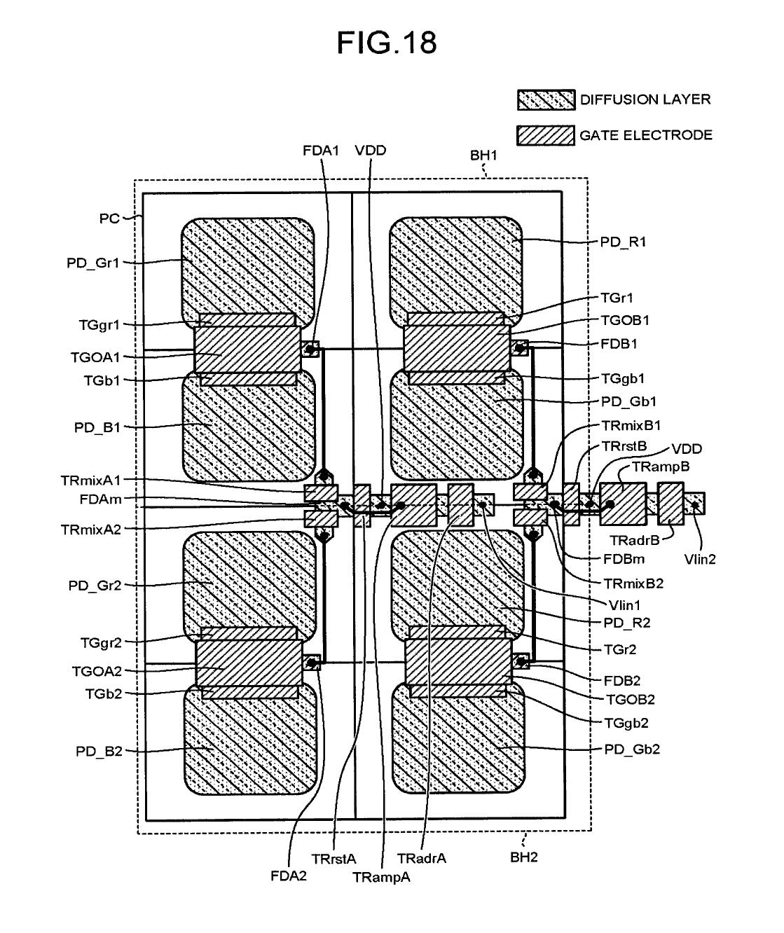

FIG. 18 is a plane view illustrating an exemplary layout configuration of the pixel of FIG. 15.

In the configuration of FIG. 18, with respect to the configuration of FIG. 14, the transfer transistor TGOA1 is arranged between the read transistors TGgr1 and TGb1, the transfer transistor TGOA2 is arranged between the read transistors TGgr2 and TGb2, the transfer transistor TGOB1 is arranged between the read transistors TGr1 and TGgb1, and the transfer transistor TGOB2 is arranged between the read transistors TGr2 and TGgb2.

The floating diffusion FDA′ is arranged to be adjacent to the transfer transistor TGOA1 in the row direction RD, the floating diffusion FDA2 is arranged to be adjacent to the transfer transistor TGOA2 in the row direction RD, the floating diffusion FDB1 is arranged to be adjacent to the transfer transistor TGOB1 in the row direction RD, and the floating diffusion FDB2 is arranged to be adjacent to the transfer transistor TGOB2 in the row direction RD.

Thus, it is possible to arrange the division transistors TRmixA1 and TRmixA2 and the transfer transistors TGOA1, TGOA2, TGOB1, and TGOB2 without undermining the uniform pixel arrangement of the Bayer arrays BH1 and BH2.

### Sixth Embodiment

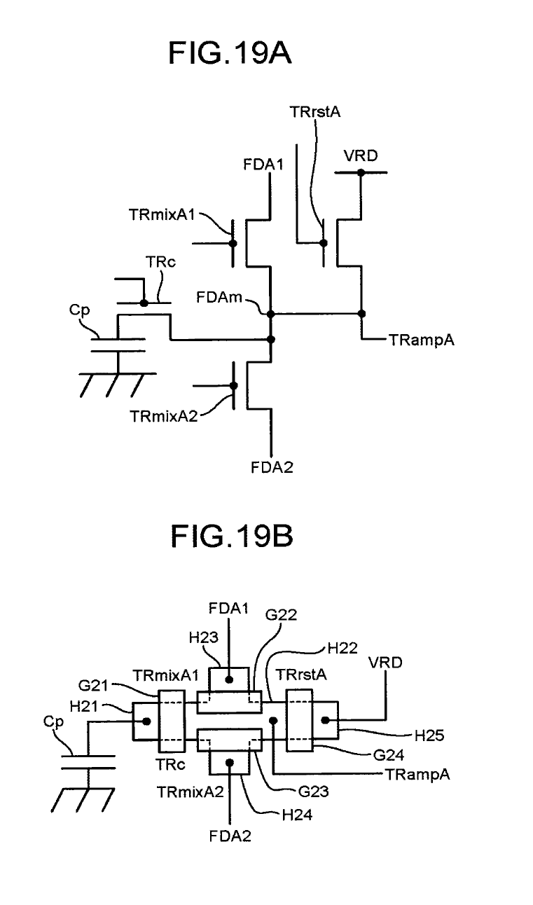

FIG. 19A is a circuit diagram illustrating an exemplary configuration of a division transistor applied to a solid-state imaging device according to a sixth embodiment, and FIG. 19B is a plane view illustrating an exemplary layout configuration of the division transistor of FIG. 19A.

In FIG. 19A, in the solid-state imaging device, a capacitor Cp is added to the floating diffusion FDAm of FIG. 9 via a coupling transistor TRc. Further, as illustrated in FIG. 19B, a coupling transistor TRc is provided with a gate electrode G21, a division transistor TRmixA1 is provided with a gate electrode G22, a division transistor TRmixA2 is provided with a gate electrode G23, and a reset transistor TRrstA is provided with a gate electrode G24. A diffusion layer H22 is formed among the gate electrodes G21 to G24, a diffusion layer H21 is formed at a side of the gate electrode G21 opposite to the diffusion layer H22, a diffusion layer H23 is formed at a side of the gate electrode G22 opposite to the diffusion layer H22, a diffusion layer H24 is formed at a side of the gate electrode G23 opposite to the diffusion layer H22, and a diffusion layer H25 is formed at a side of the gate electrode G24 opposite to the diffusion layer H22. The capacitor Cp is connected to the diffusion layer H21.

Here, as the coupling transistor TRc is turned on, it is possible to add the capacitor Cp to the floating diffusion FDAm, and it is possible to increase the saturation electron number. Further, as the gate electrode G21 is arranged to be adjacent to the floating diffusion FDAm, an interconnection for connecting the floating diffusion FDAm with the coupling transistor TRc is necessary, and thus it is possible to suppress an increase in a layout area.

### Seventh Embodiment

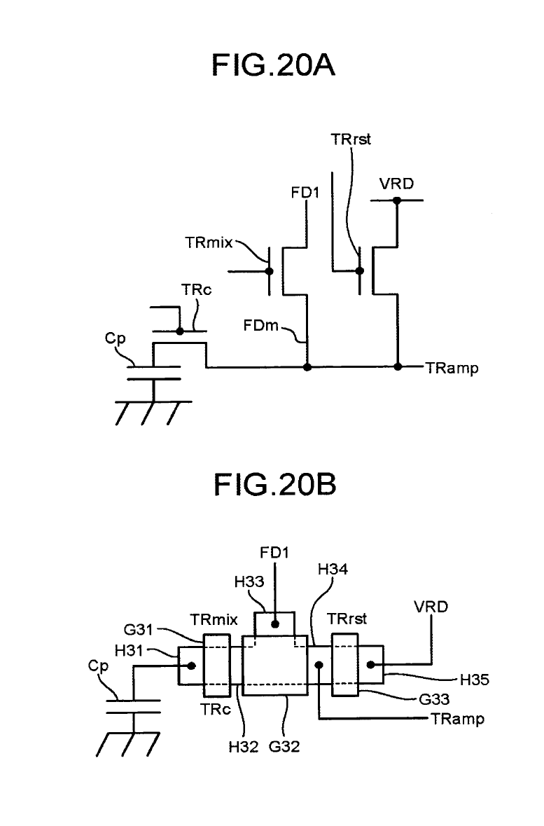

FIG. 20A is a circuit diagram illustrating an exemplary configuration of a division transistor applied to a solid-state imaging device according to a seventh embodiment, and FIG. 20B is a plane view illustrating an exemplary layout configuration of the division transistor of FIG. 20A.

In FIG. 20A, in the solid-state imaging device, a capacitor Cp is added to the floating diffusion FDm of FIG. 2 via a coupling transistor TRc. Further, as illustrated in FIG. 20B, a coupling transistor TRc is provided with a gate electrode G31, a division transistor TRmix is provided with the gate electrode G32, and a reset transistor TRrst is provided with a gate electrode G33. A diffusion layer H31 is formed between the gate electrodes G31 and G32, and a diffusion layer H34 is formed between the gate electrodes G32 and G33. The diffusion layer H31 is formed at a side of the gate electrode G31 opposite to the diffusion layer H32, and the diffusion layer H35 is formed at a side of the gate electrode G33 opposite to the diffusion layer H34. The diffusion layer H33 is formed to be adjacent to the gate electrode G32. The capacitor Cp is connected to the diffusion layer H31.

Here, it is possible to add the capacitor Cp to the floating diffusion FDm by turning on the coupling transistor TRc, and thus it is possible to increase the saturation electron number. Further, as the gate electrode G31 is arranged to be adjacent to the gate electrode G32, an interconnection for connecting the floating diffusion FDm with the coupling transistor TRc is unnecessary, and thus it is possible to suppress an increase in a layout area.

### Eighth Embodiment

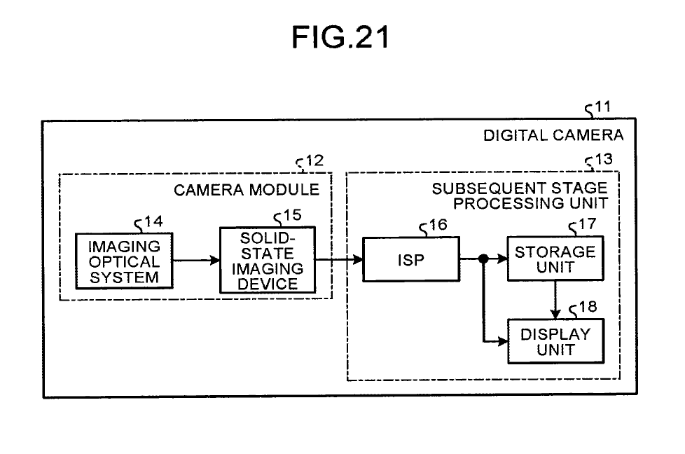

FIG. 21 is a block diagram illustrating a schematic configuration of a digital camera to which a solid-state imaging device is applied to an eighth embodiment.

Referring to FIG. 21, a digital camera 11 includes a camera module 12 and a subsequent stage processing unit 13. The camera module 12 includes an imaging optical system 14 and a solid-state imaging device 15. The subsequent stage processing unit 13 includes an image signal processor (ISP) 16, a storage unit 17, and a display unit 18. At least a part of the ISP 16 may be integrated into one chip together with the solid-state imaging device 15. As the solid-state imaging device 15, for example, any configuration of FIG. 1 and FIG. 7 or FIG. 9 and FIG. 15 may be used.

The imaging optical system 14 acquires light from a subject, and forms a subject image. The solid-state imaging device 15 images a subject image. The ISP 16 performs signal processing on an image signal obtained by the imaging by the solid-state imaging device 15. The storage unit 17 stores an image that has been subjected to the signal processing of the ISP 16. The storage unit 17 outputs the image signal to the display unit 18 according to the user's operation or the like. The display unit 18 displays an image according to the image signal input from the ISP 16 or the storage unit 17. The display unit 18 is, for example, a liquid crystal display. The camera module 12 can be applied to, for example, an electronic device such as a mobile terminal with a camera as well as the digital camera 11.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A solid-state imaging device, comprising:
a pixel that accumulates charges obtained by photoelectric conversion,
wherein the pixel includes
a photo diode that generates charges by photoelectric conversion,
a voltage converting unit that converts the charges generated by the photo diode into a voltage,
a read transistor that reads signal charges generated by the photo diode out to the voltage converting unit,
an amplifying transistor that amplifies the signal voltage converted by the voltage converting unit, and
a reset transistor that resets the voltage converting unit, and
wherein the voltage converting unit includes
a first voltage converting unit at the read transistor side,
a second voltage converting unit at the amplifying transistor side, and
a first transistor disposed between the first voltage converting unit and the second voltage converting unit.

2. The solid-state imaging device according to claim 1,
wherein the photo diode is connected to the voltage converting unit via the read transistor, and
the read transistor is connected to a gate of the amplifying transistor via the first transistor.

3. The solid-state imaging device according to claim 1,
wherein the reset transistor is connected to the second voltage converting unit.

4. The solid-state imaging device according to claim 1 further comprising,
a row selecting transistor that is connected to the amplifying transistor in series.

5. The solid-state imaging device according to claim 1, further comprising:
a column ADC circuit that calculates AD conversion values of pixel signals read from the pixels in units of columns based on a comparison result of the pixel signals and a reference voltage;
vertical signal lines that transfer the pixel signals read from the pixels to the column ADC circuit in units of columns; and
a load circuit that configures a source follower circuit with the pixels, and outputs the pixel signals from the pixels to the vertical signal lines in units of columns.

6. The solid-state imaging device according to claim 1, further comprising,
a capacitor that is connected to the second voltage converting unit via a coupling transistor.

7. The solid-state imaging device according to claim 1,
wherein a setting to a high conversion gain is performed by turning off the first transistor, and a setting to a low conversion gain is performed by turning on the first transistor.

8. The solid-state imaging device according to claim 1,
wherein the amplifying transistor and the voltage converting unit are shared by first and second pixels in a same column,
the first pixel includes
a first photo diode that generates charges by photoelectric conversion and
a first read transistor that reads the charges generated by the first photo diode out to the voltage converting unit,
the second pixel includes
a second photo diode that generates charges by photoelectric conversion and
a second read transistor that reads the charges generated by the second photo diode out to the voltage converting unit, and
the first transistor includes
a first division transistor that divides the voltage converting unit into a third voltage converting unit at the first read transistor side and the second voltage converting unit and
a second division transistor that divides the voltage converting unit into a fourth voltage converting unit at the second read transistor side and the second voltage converting unit.

9. The solid-state imaging device according to claim 4,
wherein in a first read operation, gate potential of the first division transistor is set to cause the potential of the second voltage converting unit to be deeper than the potential of the third voltage converting unit, and the charges generated by the first photo diode are detected,
in a second read operation, the gate potential of the first division transistor is set to cause the potential of the second voltage converting unit to be equal to the potential of the third voltage converting unit, and the charges generated by the first photo diode are detected,
in a third read operation, the gate potentials of the first division transistor and the second division transistor are set to cause the potential of the second voltage converting unit to be deeper than the potentials of the third voltage converting unit and the fourth voltage converting unit, and the charges generated by the first photo diode and the second photo diode are detected, and
in a fourth read operation, the gate potentials of the first division transistor and the second division transistor are set to cause the potentials of the second voltage converting unit and the third voltage converting unit to be equal to the potential of the fourth voltage converting unit, and the charges generated by the first photo diode and the second photo diode are detected.

10. The solid-state imaging device according to claim 1,
wherein the amplifying transistor and the voltage converting unit are shared by a first pixel, a second pixel, a third pixel, and a fourth pixel that are sequentially arranged in a same column,
the first pixel includes
a first photo diode that generates charges by photoelectric conversion and
a first read transistor that reads the charges generated by the first photo diode out to the voltage converting unit,
the second pixel includes
a second photo diode that generates charges by photoelectric conversion and
a second read transistor that reads the charges generated by the second photo diode out to the voltage converting unit, and
the third pixel includes
a third photo diode that generates charges by photoelectric conversion and
a third read transistor that reads the charges generated by the third photo diode out to the voltage converting unit,
the fourth pixel includes
a fourth photo diode that generates charges by photoelectric conversion and
a fourth read transistor that reads the charges generated by the fourth photo diode out to the voltage converting unit, and
the division transistor includes
a first division transistor that divides the voltage converting unit into a third voltage converting unit at the first read transistor side and the second read transistor side and the second voltage converting unit and
a second division transistor that divides the voltage converting unit into a fourth voltage converting unit at the third read transistor side and the fourth read transistor side and the second voltage converting unit.

11. The solid-state imaging device according to claim 10,
wherein the second voltage converting unit is arranged between the second pixel and the third pixel, the third voltage converting unit is arranged between the first pixel and the second pixel, and the fourth voltage converting unit is arranged between the third pixel and the fourth pixel.

12. The solid-state imaging device according to claim 11,
wherein the first division transistor and the second division transistor are arranged to be adjacent in the column direction between the second pixel and the third pixel.

13. The solid-state imaging device according to claim 11,
wherein the first transistor, the amplifying transistor, and the reset transistor are arranged to be adjacent to in the row direction between the second pixel and the third pixel.

14. The solid-state imaging device according to claim 10,
wherein a first Bayer array is configured with the first and second pixels belonging to a first column and the first and second pixels belonging to a second column neighboring to the first column, and
a second Bayer array is configured with the third and fourth pixels belonging to the first column and the third and fourth pixels belonging to the second column.

15. The solid-state imaging device according to claim 14,
wherein the second voltage converting unit is arranged between the first Bayer array and the second Bayer array.

16. The solid-state imaging device according to claim 15,
wherein the first division transistor, the second division transistor, the amplifying transistor, and the reset transistor are arranged between the first Bayer array and the second Bayer array.

17. The solid-state imaging device according to claim 1, further comprising,
a transfer transistor that is arranged between the read transistor and the first transistor.

18. The solid-state imaging device according to claim 17,
wherein a gate of the transfer transistor is arranged above the first voltage converting unit.

19. A solid-state imaging device, comprising:
a pixel that accumulates charges obtained by photoelectric conversion,
wherein the pixel includes
a photo diode that generates charges by photoelectric conversion,
a voltage converting unit that converts the charges generated by the photo diode into a voltage,
a read transistor that reads signal charges generated by the photo diode out to the voltage converting unit,
an amplifying transistor that amplifies the signal voltage converted by the voltage converting unit,
a reset transistor that resets the voltage converting unit, and
a division transistor that divides the voltage converting unit, and changes a conversion gain of the voltage converting unit.

20. The solid-state imaging device according to claim 19,
wherein the photo diode is connected to the voltage converting unit via the read transistor, and
the read transistor is connected to a gate of the amplifying transistor via the division transistor.
